(19) United States
(12) Patent Application Publication
(10) Pub. No.: US 2024/0376637 A1
(43) Pub. Date: Nov. 14, 2024

(54) Method for Producing Semiconductor Nanoparticles, and Semiconductor Nanoparticles

(71) Applicant: Panasonic Intellectual Property Management Co., Ltd., Osaka (JP)

(72) Inventors: Yoshie TAKAHASHI, Osaka (JP); Kazuto FUKUDA, Osaka (JP)

(21) Appl. No.: 18/741,854

(22) Filed: Jun. 13, 2024

Related U.S. Application Data
(63) Continuation of application No. PCT/JP2022/042486, filed on Nov. 16, 2022.

(30) Foreign Application Priority Data
Dec. 23, 2021 (JP) 2021-209464

(51) Int. Cl. C30B 29/48; C30B 7/04

(52) U.S. Cl. CPC C30B 29/48; C30B 7/04

(57) ABSTRACT

A method for producing a semiconductor nanoparticle includes: mixing a Zn ion source solution and a Te ion source solution and preparing a precursor solution; and placing the precursor solution in a closed container and heating the precursor solution. The adjusting the precursor solution includes adjusting a pH of the precursor solution to 5 or more and 9 or less, and the preparing the precursor solution and the heating the precursor solution include removing oxygen in the precursor solution to have an oxygen concentration of 2 mg/L or less in the precursor solution.

### TECHNICAL FIELD

The present invention relates to a method for producing a semiconductor nanoparticle and a semiconductor nanoparticle.

### BACKGROUND ART

A semiconductor nanoparticle is a nanometer-sized microcrystal produced by chemical synthesis, and has a characteristic that a physical quantity such as band gap energy can be adjusted according to a particle size unlike a bulk material. A semiconductor nanoparticle, which is also referred to as a quantum dot, is attracting attention as a next-generation luminescence material because it can adjust not only a material composition but also band gap energy, that is, an emission wavelength according to a particle size due to the quantum size effect.

Furthermore, the semiconductor nanoparticle is characterized by having a narrow emission half width at half maximum (FWHM) as a characteristic of the luminescence material, unlike a phosphor or a fluorescent dye. There are two major physical properties that affect the emission half width at half maximum. First, as described above, since the emission wavelength can be adjusted according to the particle size, the particle size distribution contributes to the emission half width at half maximum. The second is that there are few crystal defects. In a case where there is a crystal defect, a defect level is generated, and energy is released with an energy lower than the original band gap energy. When there are a large number of defect levels, energy is released at various levels, so that the emission half width at half maximum is widened.

Conventionally, representative examples of semiconductor nanoparticles include cadmium selenide (CdSe) and cadmium telluride (CdTe) using cadmium (Cd), and mixed crystal materials thereof. These semiconductor nanoparticles are characterized by a narrow emission half width at half maximum, and have been partly put into practical use mainly in a display field. However, Cd is very toxic, and therefore its use is restricted, and it is regarded as a material to be reduced. Toxicity is a very important item also in a field of biosciences, and Cd-free semiconductor nanoparticles are desired.

On the other hand, many developments in the Cd-free semiconductor nanoparticles have also been studied. Most of them are synthesis studies in an organic solvent, and a so-called hot soap method in which an ion source of an element constituting nanoparticles is reacted in an organic solvent is known (see, for example, NPL 1).

However, for example, in the case of being used as a fluorescent marker in the bioscience field such as bioimaging and bioassay, water solubility is essential. As the semiconductor nanoparticles produced in an organic solvent, a long-chain aliphatic amine-based compound, an aliphatic phosphine-based compound, an aliphatic carboxylic acid-based compound, or the like, which is generally a hydrophobic ligand, is used. Therefore, in the case of use in the field of biosciences, a step of substituting a ligand with a water-soluble short-chain mercapto-based compound or the like, or a coating step with an amphiphilic polymer is required, and the process becomes complicated.

In order to cope with these problems, an ion source constituting nanoparticles using a non-cadmium material is reacted in an aqueous solution to be synthesized (see, for example, PTL 1).

### CITATION LIST

### Patent Literature

PTL 1: Unexamined Japanese Patent Publication No. 2019-34873

### Non-Patent Literature

NPL 1: Jun Zhang, Shengye Jin, H. Christopher Fry, Sheng Peng, Elena Shevchenko, Gary P. Wiederrecht, and Tijana Rajh, J. Am. Chem. Soc, vol. 133, No. 31, 2011, 15324-15327

### SUMMARY OF THE INVENTION

However, the semiconductor nanoparticle synthesized by the above method (PTL 1) has a problem that the emission half width at half maximum is wide and the S/N is low in order to perform multicolor staining required in the field of biosciences.

The present invention has been made to solve the above-mentioned conventional problems, and an object of the present invention is to provide a method for producing a semiconductor nanoparticle free of cadmium and having a narrow emission half width at half maximum of an emission spectrum.

In order to achieve the above object, a method for producing a semiconductor nanoparticle according to the present invention includes: mixing a Zn ion source solution and a Te ion source solution and preparing a precursor solution; and placing the precursor solution in a closed container and heating the precursor solution. The adjusting the precursor solution includes adjusting a pH of the precursor solution to 5 or more and 9 or less, and the preparing the precursor solution and the heating the precursor solution include removing oxygen in the precursor solution to have an oxygen concentration of 2 mg/L or less in the precursor solution.

As described above, according to the method for producing a semiconductor nanoparticle according to the present disclosure, it is possible to provide a semiconductor nanoparticle with narrow emission spectrum and emission half width at half maximum.

### BRIEF DESCRIPTION OF THE DRAWINGS

FIG. 1 is a flowchart illustrating each step of a method for producing a semiconductor nanoparticle according to a first exemplary embodiment.

FIG. 2(a) is a schematic cross-sectional view illustrating a cross-sectional structure of a semiconductor nanoparticle according to the first exemplary embodiment, and FIG. 2 (b) is a schematic cross-sectional view illustrating a cross-sectional structure of a semiconductor nanoparticle of a modification.

FIG. 3 is a diagram illustrating an absorption spectrum in a semiconductor nanoparticle according to Example 1.

FIG. 4 is a diagram illustrating an emission spectrum in the semiconductor nanoparticle according to Example 1.

FIG. 5 is a TEM image of the semiconductor nanoparticle according to Example 1.

FIG. 6(a) is an XRD pattern of the semiconductor nanoparticle according to Example 1, and FIG. 6(b) is an XRD pattern of a semiconductor nanoparticle according to Comparative Example 3.

FIG. 7 is a diagram illustrating results of Examples and Comparative Examples in the first exemplary embodiment.

### DESCRIPTION OF EMBODIMENT

A method for producing a semiconductor nanoparticle according to a first aspect includes: mixing a Zn ion source solution and a Te ion source solution and preparing a precursor solution which is mixed solution; and heating the precursor solution in a closed container, in which the adjusting the precursor solution includes setting a pH of the precursor solution to 5 or more and 9 or less, and the preparing the precursor solution and the heating the precursor solution include setting an oxygen concentration in solution to 2 mg/L or less.

In the method for producing a semiconductor nanoparticle according to the second aspect, in the first aspect, the preparing the precursor solution may include containing a ligand in the precursor solution.

In the method for producing a semiconductor nanoparticle according to the third aspect, in the second aspect, the ligand may be water-soluble and may contain a mercapto group or a disulfide group.

In the method for producing a semiconductor nanoparticle according to the fourth aspect, in any one of the first to third aspects, in the adjusting the precursor solution, in a molar ratio of Zn ions, Te ions, and the ligand, where 1 is for Zn ions, a is for Te ions, and b is for the ligand, a may be 0.03 or more and 0.90 or less, and b may be 1.0 or more and 9.0 or less.

In any one of the first to fourth aspects, the method for producing semiconductor nanoparticles according to the fifth aspect may further include cooling the precursor solution placed in the closed container.

In the method for producing a semiconductor nanoparticle according to a sixth aspect, in any one of the first to fifth aspects, the heating the precursor solution in the closed container may include heating at a temperature of 60° C. or more and 300° C. or less.

A semiconductor nanoparticle according to a seventh aspect includes: a core part having a zinc blende structure of ZnTe; and a ligand bonded to an atom on a surface of the core part.

In the semiconductor nanoparticle according to the eighth aspect, in the seventh aspect, the ligand may be water-soluble and may contain a mercapto group or a disulfide group.

In the semiconductor nanoparticle according to the ninth aspect, in the seventh or eighth aspect, a composition of the semiconductor nanoparticle may satisfy an S/Te ratio of 2.7×d∧(−1.2)>S/Te.

In the semiconductor nanoparticle according to the tenth aspect, in any one of the seventh to ninth aspects, the semiconductor nanoparticle may have a particle size of 10 nm or less.

In the semiconductor nanoparticle according to the eleventh aspect, in any one of the seventh to tenth aspects, the semiconductor nanoparticle may have an emission half width at half maximum of 50 nm or less.

In the semiconductor nanoparticle according to the twelfth aspect, in any one of the seventh to eleventh aspects, a difference between a peak position in an absorption spectrum and a peak position in an emission spectrum of the semiconductor nanoparticle may be 60 nm or less.

Hereinafter, a semiconductor nanoparticle according to an exemplary embodiment and a method for producing the same will be described with reference to the accompanying drawings. Note that substantially identical members are denoted by identical reference marks in the drawings.

### First Exemplary Embodiment

### <Method for Producing Semiconductor Nanoparticle>

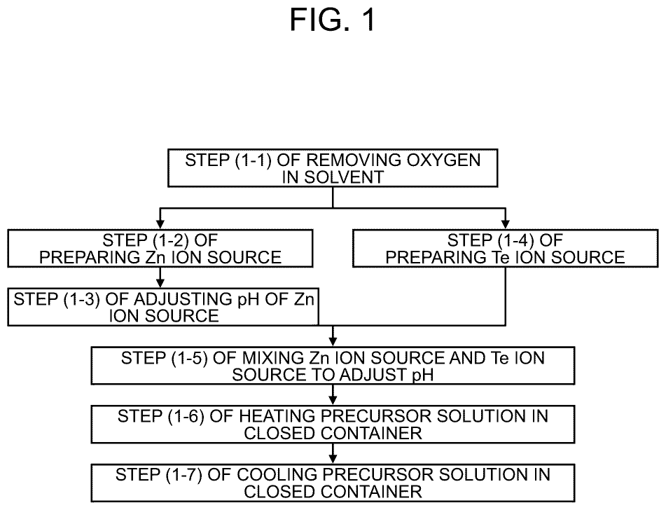

FIG. 1 is a flowchart illustrating each step of a method for producing a semiconductor nanoparticle according to a first exemplary embodiment. As illustrated in FIG. 1, a method for producing a semiconductor nanoparticle according to the first exemplary embodiment includes seven steps of a step (1-1) of removing oxygen in a solvent, a step (1-2) of preparing a Zn ion source, a step (1-3) of adjusting a pH of the Zn ion source, a step (1-4) of preparing a Te ion source, a step (1-5) of mixing the Zn ion source and the Te ion source to adjust a pH, a step (1-6) of heating a precursor solution in a sealed manner, and a step (1-7) of cooling the precursor solution.

### (1) Step (1-1) of Removing Oxygen in Solvent

First, step (1-1) of removing oxygen in a solvent is a step of removing oxygen in a solvent used for producing a semiconductor nanoparticle. The solvent is, for example, water. An oxygen concentration in the solvent is, for example, preferably 2 mg/L or less, further preferably 1 mg/L or less, and more preferably 0.2 mg/L or less. When the oxygen concentration in the solvent is higher than 2 mg/L, Te ions are oxidized in the process of producing a semiconductor nanoparticle, and a part of the Te ions becomes polytelluride (Na₂ Teₓ, K₂Teₓ: x>1), so that the crystallinity is lowered and an emission half width at half maximum of an emission spectrum is widened.

Here, the method for removing oxygen in the solvent is not particularly limited, and any method may be used as long as the oxygen concentration in the solvent is 2 mg/L or less in all the steps of the precursor solution preparation steps (1-1 to 1-5) and the heating and cooling steps (1-6, 1-7). For example, oxygen in the solvent can be removed within the above range by stirring the solvent under an inert gas atmosphere or bubbling an inert gas under an inert gas atmosphere. On the other hand, for example, in a case where a solvent is stirred in the air or an inert gas is bubbled in the air instead of the inert gas atmosphere, a low oxygen concentration in the solvent cannot be maintained. Therefore, the step of removing oxygen in the solvent and each step of the production process are preferably performed under the inert gas atmosphere. Examples of the inert gas include nitrogen and argon. Here, the oxygen concentration in the solvent can be measured by, for example, a dissolved oxygen meter.

Te is very easily oxidized, and in order to maintain Te²⁻(−II) in the solvent, for example, the oxygen concentration in the solvent may be 2 mg/L or less in all steps by stirring the solvent under the inert gas atmosphere or bubbling an inert gas under the inert gas atmosphere.

### (2) Step (1-2) of Preparing a Zn Ion Source

Next, step (1-2) of preparing a Zn ion source will be described. This step is a step of dissolving a material serving as a Zn ion source and a ligand in a solvent.

The material serving as the Zn ion source is not particularly limited as long as it is water-soluble, but zinc chloride, zinc perchlorate, zinc acetate, zinc nitrate, and the like can be used.

The material serving as the ligand may be any material as long as it forms a complex with a Zn ion in the production process, and the reactivity can be controlled by the concentration, pH, and material type thereof. Furthermore, the ligand also affects the dispersibility of the semiconductor nanoparticles after completion of the reaction. The material of the ligand may be any material that is water-soluble and contains a mercapto group or a disulfide group. Furthermore, although not particularly limited, a material containing one or more water-soluble functional groups such as a carboxylic acid, an amine, an amide, and a hydroxyl group is preferable. As the material of the ligand, for example, mercaptopropionic acid, thioglycolic acid, mercaptoethanol, aminoethanethiol, N-acetyl-L-cysteine, L-cysteine, or the like can be used.

### (3) Step (1-3) of Adjusting pH of Zn Ion Source

Step (1-3) of adjusting a pH of the Zn ion source will be described. The material for adjusting the pH is not particularly limited, but for example, in the case of adjusting the pH to an alkaline side, a sodium hydroxide aqueous solution, a potassium hydroxide aqueous solution, an ammonia aqueous solution, or the like can be used. In the case of adjusting to an acid side, a hydrochloric acid aqueous solution, a nitric acid aqueous solution, or the like can be used. Note that the material used for the pH adjustment is not particularly limited, but by using a strong acid or a strong base, an amount used for the pH adjustment can be reduced, and a change in the concentration of each raw material during the pH adjustment can be suppressed.

As a pH range to be adjusted, the pH is preferably 5.0 or more and 9.0 or less. It is more preferably 5.5 or more and 8.5 or less. In a case where the pH is lower than 5.0, the dispersion state of the complex is deteriorated, and the complex is easily aggregated. In a case where the pH is higher than 9.0, an amount of hydroxyl groups is excessive and complex formation with a ligand is inhibited, so that it is difficult to control the synthesis reaction.

### (4) Step (1-4) of Preparing Te Ion Source

Step (1-4) of preparing a Te ion source is a step of dissolving a material serving as the Te ion source in a solvent. Note that step (1-4) does not need to be performed after step (1-2) and step (1-3), and may be performed after step (1-1), and can be performed in parallel with step (1-2) and step (1-3).

As a material serving as a Te ion source, hydrogen telluride, sodium hydrogen telluride, sodium telluride, potassium hydrogen telluride, potassium telluride, or the like can be used.

The Te ion source can be obtained by dissolving the material of the Te ion source in a solvent, for example, water to obtain a Te (−II) aqueous solution, or by reducing metal Te in, for example, a potassium borohydride aqueous solution to obtain a Te (−II) aqueous solution.

### (5) Step (1-5) of Mixing Zn Ion Source and Te Ion Source to Adjust pH

Step (1-5) of mixing the Zn ion source and the Te ion source to adjust the pH is a step of mixing the solution of the pH-adjusted Zn ion source obtained in the step (1-3) and the solution of the Te ion source obtained in the step (1-4) in predetermined amounts, and adjusting the pH of the mixed solution (hereinafter, it is referred to as a “precursor”).

A material for adjusting the pH of the precursor is not particularly limited, but for example, in the case of adjusting the pH to the alkaline side, an aqueous solution of sodium hydroxide, an aqueous solution of potassium hydroxide, an aqueous solution of ammonia, or the like can be used. In the case of adjusting to an acid side, a hydrochloric acid aqueous solution, a nitric acid aqueous solution, or the like can be used. Note that the material used for the pH adjustment is not particularly limited, but by using a strong acid or a strong base, an amount used for the pH adjustment can be reduced, and a change in the concentration of each raw material during the pH adjustment can be suppressed.

As a pH range to be adjusted, the pH is preferably 5.0 or more and 9.0 or less. It is more preferably 5.5 or more and 8.5 or less. In a case where the pH is lower than 5.0, the dispersion state of the ligand is deteriorated, so that aggregation easily occurs. In a case where the pH is higher than 9.0, an amount of hydroxyl groups is excessive, so that a surface state of the semiconductor nanoparticles is deteriorated, aggregation easily occurs, and light emission is not observed.

### (6) Step (1-6) of Placing Precursor in Closed Container and Heating

Step (1-6) of placing the precursor in a closed container and heating the precursor is a step of generating crystal nuclei of ZnTe from each ion source in the precursor by heating and growing the crystals. In this case, in a case where the solvent is water, so-called hydrothermal synthesis is performed at a heating temperature and a pressure corresponding to a saturated vapor pressure of water which is a solvent corresponding to the heating temperature.

The closed container is not particularly limited, but water as a solvent is evaporated by heating, and the pressure in the closed container increases corresponding to the saturated vapor pressure of water. Therefore, the closed container may be a pressure-resistant container that can withstand the pressure. As the reaction vessel, for example, glass, metal, fluorine-processed metal, fluororesin insert, or the like can be used. Note that a usable reaction vessel may be appropriately selected according to the operating temperature range.

The heating temperature is, for example, preferably 60° C. or higher and 300° C. or lower, and more preferably 80° C. or higher and 280° C. or lower. At temperatures below 60° C., it takes a long time for the crystal growth, which reduces productivity. At a temperature higher than 300° C., thermal decomposition of the ligand proceeds before crystal growth, so that the dispersed state of the semiconductor nanoparticles cannot be maintained, and aggregation occurs.

### (7) Step (1-7) of Cooling Heated Closed Container

Step (1-7) of cooling the heated closed container is a step of lowering the temperature and stopping the crystal growth.

The cooling method is not particularly limited as long as it can be cooled to room temperature, and examples thereof include natural cooling, cooling with cold air, cold water, or an ice bath, and cooling in a heat insulating container.

### <Regarding Amount of Raw Material Charged>

Furthermore, in a case where the Zn ions are 1, the Te ions are a, and the ligand is b, a is preferably 0.03 or more and 0.90 or less, and more preferably 0.05 or more and 0.75 or less in a charged mixing molar ratio of the Zn ions, the Te ions, and the ligand. b is preferably 1.0 or more and 9.0 or less, and more preferably 1.2 or more and 7.5 or less. In a case where the ratio a (Te/Zn) of the Te ions to the Zn ions is less than 0.03, an ion source necessary for crystal growth is insufficient, and the crystal does not grow sufficiently. Furthermore, in a case where the ratio a (Te/Zn) of the Te ions to the Zn ions is more than 0.90, the reactivity with the Zn ions cannot be controlled, and the crystallinity decreases. In a case where the ratio b (ligand/Zn ions) of the ligand to the Zn ions is less than 1.0, the dispersed state cannot be maintained and aggregation occurs. Furthermore, in a case where the ratio b (ligand/Zn ions) of the ligand to the Zn ions is more than 9.0, the crystal growth is inhibited, so that it takes time for crystal growth, and during that time, thermal decomposition of the ligand also occurs, so that the crystallinity of ZnTe decreases.

### <Semiconductor Nanoparticle>

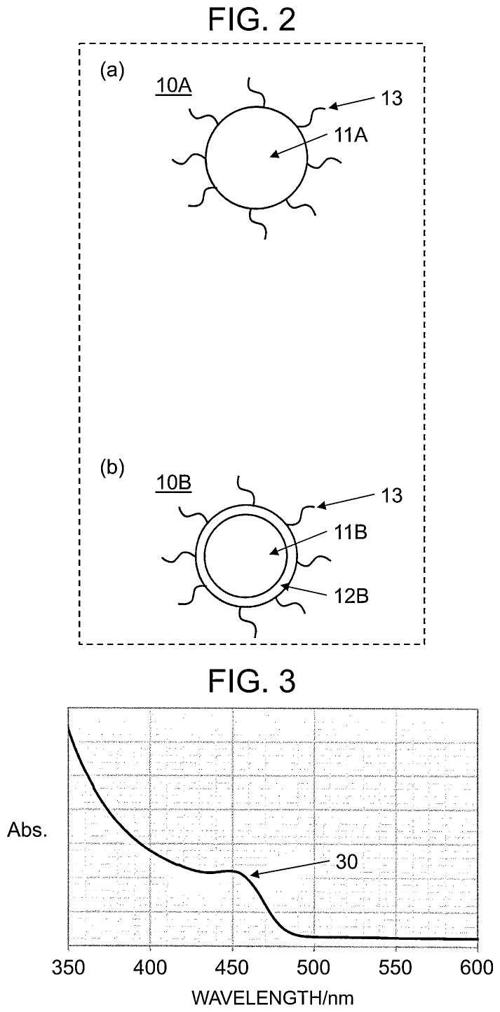

Subsequently, a schematic diagram of semiconductor nanoparticles (10A, 10B) according to the first exemplary embodiment is illustrated in FIG. 2. Semiconductor nanoparticles (10A, 10B) illustrated in FIG. 2 are a semiconductor microcrystalline body containing no Cd.

The semiconductor nanoparticles according to the first exemplary embodiment have a particle size of 10 nm or less. Moreover, the particle size may be 5 nm or less.

As illustrated in FIG. 2(a), semiconductor nanoparticle (10A) includes core part (11A) and ligand (13A). On the other hand, as illustrated in FIG. 2(b), semiconductor nanoparticle (10B) of a modification may have a core-shell structure of core part (11B), shell part (12B) covering the core part, and ligand (13B).

Core parts (11A, 11B) mainly contain Zn and Te, but may contain elements other than these elements. However, regulated substances such as Cd and Pb are not included beyond an allowable range of the regulation value.

Core parts (11A, 11B) have a zinc blende structure of ZnTe.

As described in the above production process, ligand (13) is water-soluble and contains a mercapto group (thiol group: —SH) or a disulfide group (—S—S—). Furthermore, although not particularly limited, a material containing one or more water-soluble functional groups such as a carboxylic acid, an amine, an amide, and a hydroxyl group is preferable. As the ligand, for example, mercaptopropionic acid, thioglycolic acid, mercaptoethanol, aminoethanethiol, N-acetyl-L-cysteine, L-cysteine, or the like can be used. Furthermore, not one type but a combination of a plurality of types can be used.

In semiconductor nanoparticle (10A) according to the first exemplary embodiment, a difference between peak position (30) of the absorption spectrum and peak position (40) of the emission spectrum is 60 nm or less. The difference is more preferably 50 nm or less. In a case where a crystal defect is present, the semiconductor nanoparticle forms a defect level, and therefore emits energy lower than the absorbed energy. That is, when crystal defects are present, the peak position of the emission spectrum shifts to a longer wavelength side than the peak position of the absorption spectrum. Therefore, when the peak position of the absorption spectrum and the peak position of the emission spectrum are 60 nm or less, semiconductor nanoparticles having few crystal defects can be produced.

Furthermore, semiconductor nanoparticle (10A) according to the present exemplary embodiment has emission half width at half maximum (41) of 50 nm or less. The emission half width at half maximum is more preferably 45 nm or less. Here, the emission half width at half maximum is an index representing the spread of the emission spectrum derived from the semiconductor nanoparticle, and refers to the spread of the spectrum at a half value of the emission peak intensity. By obtaining an emission spectrum having a narrow emission half width at half maximum as described above, in a case where a plurality of types of semiconductor nanoparticles having different emission peak wavelengths is simultaneously used in bioimaging or the like, overlapping of spectra is reduced, and a clear imaging image is obtained.

Since the semiconductor nanoparticle is a particle having a nanometer size, the influence of the surface state thereof is large. For example, in a case where the particle size of the semiconductor nanoparticle is 5 nm, when the total number of atoms is about 4400, the number of atoms on the surface accounts for 40% or more of the entire particles. The semiconductor nanoparticle is a microcrystalline body, and has a large amount of dangling bonds on its surface. When the surface level is formed by the dangling bond on the surface, light emission derived from the semiconductor nanoparticle is not observed. Therefore, it is necessary to deactivate the surface state of the semiconductor nanoparticle, that is, the surface level due to the dangling bond on the surface. For example, dangling bonds on the surface can be reduced by bonding a surface atom to a ligand or bonding a surface atom to another material serving as a shell part covering the core.

In this case, as described above, the ligand includes a mercapto group (thiol group: —SH) or a disulfide group (—S—S—). That is, a ligand containing a certain amount of sulfur S is present on the surface, and dangling bonds on the surface can be reduced by bonding with surface atoms.

Therefore, as the composition of semiconductor nanoparticles (10A), it is preferable that an S/Te ratio, which is an atomic ratio between sulfur S and tellurium Te, satisfies 2.7×d∧(−1.2)>S/Te, where the particle size is d nm. On the other hand, in a case where the S/Te ratio does not satisfy 2.7×d∧(−1.2)>S/Te, the ligand is not sufficiently bonded to the surface atom, and a dangling bond exists on the surface of semiconductor nanoparticle (10A). Therefore, light emission derived from semiconductor nanoparticles is not observed.

A material of shell part (12) of the semiconductor nanoparticle according to the modification is not particularly limited, but for example, a material having an energy gap higher than that of ZnTe, such as zinc sulfide (ZnS) or zinc selenide (ZnSe), is preferable.

Hereinafter, examples and comparative examples in experiments performed by the inventors will be described.

### Example 1

In Example 1, semiconductor nanoparticles were produced by the following production method.
(1) First, ultrapure water was stirred under a nitrogen atmosphere to confirm that the oxygen concentration was 0.2 mg/L, and the subsequent steps were all performed under the nitrogen atmosphere.
(2) As preparation of a Zn ion source, 0.2 mmol of zinc chloride (special grade manufactured by KANTO CHEMICAL CO., INC.) and 0.39 mmol of N-acetyl-L-cysteine (special grade manufactured by Kishida Chemical Co., Ltd.) were dissolved in 10 ml of the ultrapure water.
(3) Thereafter, the pH was adjusted to 7 with potassium hydroxide (special grade manufactured by Wako Pure Chemical Industries, Ltd.).
(4) Next, as a preparation of a Te ion source, sodium hydrogen telluride was dissolved to prepare the Te ion source.
(5) Thereafter, the Te ion source was added to the Zn ion source so as to be 0.016 mmol, and the pH was adjusted to 7 with hydrochloric acid (KANTO CHEMICAL CO., INC., special grade).
(6) The prepared precursor was transferred to a closed container and heated at 150° C. for 50 minutes.
(7) Thereafter, the mixture was cooled to room temperature.

Semiconductor nanoparticles according to Example 1 were obtained through the above steps.

### (Evaluation of Absorption Spectrum)

The absorption spectrum of the obtained reaction solution was measured with an ultraviolet-visible spectrophotometer (UV-mini-1240: manufactured by Shimadzu Corporation). An absorption spectrum obtained for the semiconductor nanoparticle according to Example 1 is illustrated in FIG. 3. As illustrated in FIG. 3, in the semiconductor nanoparticle according to Example 1, a peak position of the absorption spectrum was 2.725 eV. That is, a peak caused by the semiconductor nanoparticle could be observed at an absorption wavelength of about 455 nm.

### (Evaluation of Emission Spectrum)

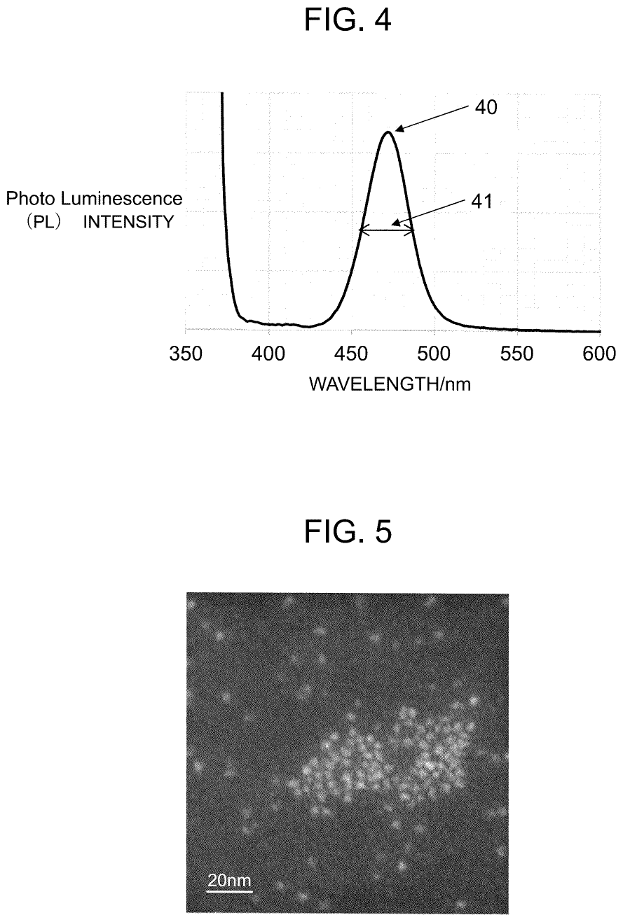

Furthermore, an emission spectrum of the obtained reaction solution was measured by a quantum efficiency measurement system (QE-2000: manufactured by Otsuka Electronics Co., Ltd.), and the emission could be confirmed. The emission spectrum obtained for the semiconductor nanoparticle according to Example 1 is illustrated in FIG. 4. As illustrated in FIG. 4, in the semiconductor nanoparticle according to Example 1, a peak position of the emission spectrum was 2.632 eV. That is, a peak caused by the semiconductor nanoparticle could be observed at an emission wavelength of about 471 nm. An emission half width at half maximum (emission full width at half maximum) was 31.2 nm.

### (Difference Between Absorption Peak Position and Emission Peak Position)

A difference between the peak positions of the obtained absorption spectrum and emission spectrum was 16.8 nm in the semiconductor nanoparticle according to Example 1.

### (Measurement of Particle Size)

Isopropyl alcohol (KANTO CHEMICAL CO., INC., special grade) was added to the obtained reaction solution to form a precipitate, and the precipitate was separated by centrifugation (3K₃₀C: manufactured by Sigma). The precipitate was again dispersed in ultrapure water, and the dispersion was dropped onto a TEM grid and dried. TEM measurement of the semiconductor nanoparticles on the grid was performed, and the particle size by number average was calculated. In the semiconductor nanoparticles according to Example 1, an average particle size calculated from the TEM image of the semiconductor nanoparticles according to Example 1 in FIG. 5 was 3.2 nm. Note that, in FIG. 5, a white circular part where a lattice image was observed was defined as a semiconductor nanoparticle.

### (Composition Analysis)

Isopropyl alcohol (KANTO CHEMICAL CO., INC., special grade) was added to the obtained reaction solution to form a precipitate, and the precipitate was separated by centrifugation (3K₃₀C: manufactured by Sigma). The precipitate was subjected to composition analysis by SEMEDX. As a result, in the semiconductor nanoparticles according to Example 1, the S/Te ratio was 1.63, which satisfied 2.7× d∧(−1.2)>S/Te.

### (Crystal Structure Analysis)

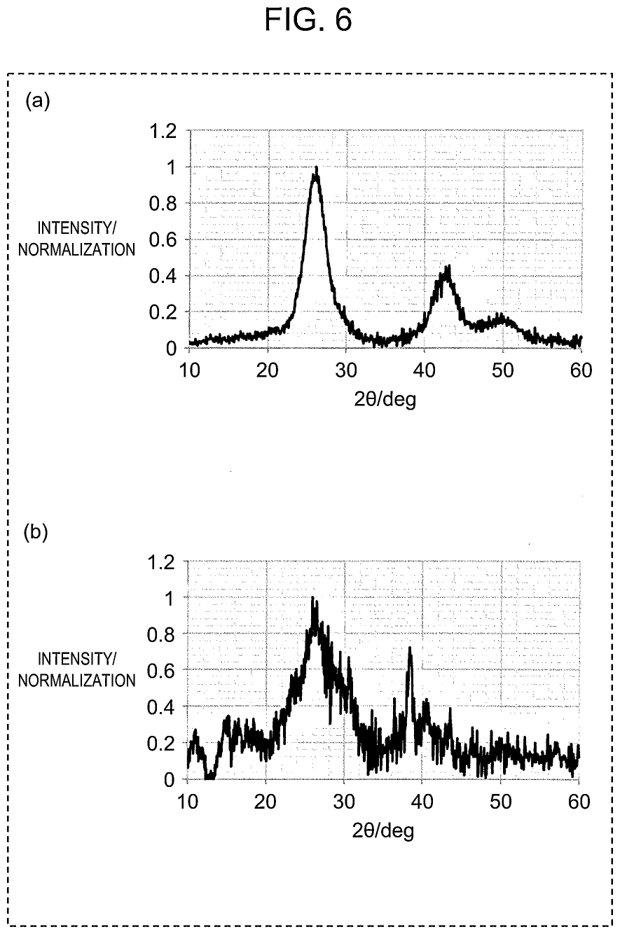

Isopropyl alcohol (KANTO CHEMICAL CO., INC., special grade) was added to the obtained reaction solution to form a precipitate, and the precipitate was separated by centrifugation (3K₃₀C: manufactured by Sigma). The precipitate was subjected to crystal structure analysis by XRD, and in the semiconductor nanoparticles according to Example 1, it was confirmed that the obtained XRD pattern was a pattern derived from a zinc blende structure of ZnTe as illustrated in FIG. 6(a).

### Example 2

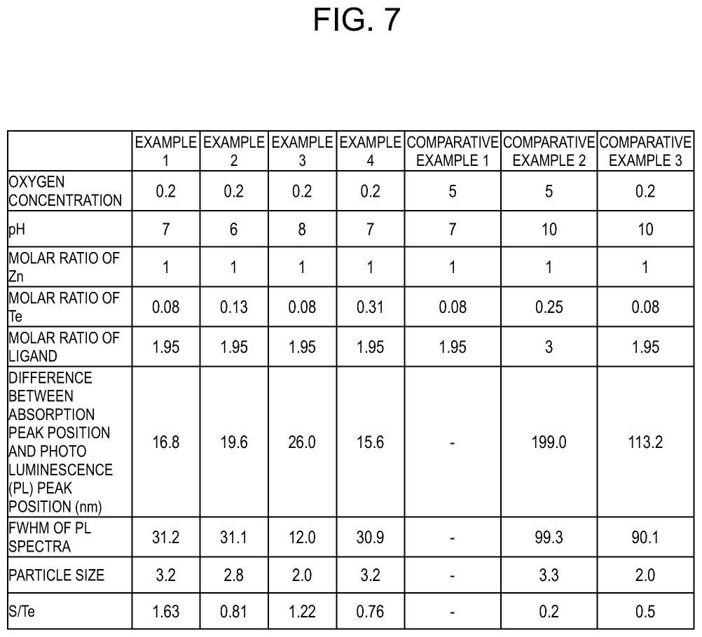

In Example 2, semiconductor nanoparticles were produced in the same manner as in Example 1 except that the composition ratio and the pH were adjusted as illustrated in FIG. 7, and the heating time was changed to 60 minutes. The evaluation was performed in the same manner as in Example 1.

### Example 3

In Example 3, semiconductor nanoparticles were produced in the same manner as in Example 1 except that the composition ratio and the pH were adjusted as illustrated in FIG. 7, and the heating time was changed to 20 minutes. The evaluation was performed in the same manner as in Example 1.

### Example 4

In Example 4, the composition ratio and pH were adjusted as illustrated in FIG. 7, and semiconductor nanoparticles were prepared in the same manner as in Example 1 except for the adjustment. The evaluation was performed in the same manner as in Example 1.

### Comparative Example 1

In Comparative Example 1, the oxygen concentration in the solution was adjusted to 5 mg/L, and semiconductor nanoparticles were produced in the same manner as in Example 1 except for the oxygen concentration. The evaluation was performed in the same manner as in Example 1.

### Comparative Example 2

In Comparative Example 2, semiconductor nanoparticles were produced in the same manner as in Example 1 except that the oxygen concentration in the solution was adjusted to 5 mg/L, the composition ratio and the pH were adjusted as illustrated in FIG. 7, and the heating time was changed to 5 minutes. The evaluation was performed in the same manner as in Example 1.

### Comparative Example 3

In Comparative Example 3, the oxygen concentration in the solution was adjusted to 0.2 mg/L, and semiconductor nanoparticles were produced in the same manner as in Comparative Example 2 under the other conditions. The evaluation was performed in the same manner as in Example 1. In the semiconductor nanoparticle according to Comparative Example 3, as illustrated in FIG. 6(b), in the obtained XRD pattern, it was confirmed that the pattern derived from the zinc blende structure of ZnTe is not the pattern of the main phase.

Preparation conditions and measurement results in each of Examples 1 to 4 and Comparative Examples 1 to 3 are illustrated in FIG. 7. Regarding Comparative Example 1, since the obtained solution did not emit light, the subsequent evaluation was not performed.

As is apparent from FIG. 7, in any of the semiconductor nanoparticles according to Examples 1 to 4, an emission half width at half maximum of 45 nm or less can be realized, and S/N required by bioimaging, bioassay, or the like can be realized.

Note that the present disclosure includes an appropriate combination of any exemplary embodiment and/or example among the various above-described exemplary embodiments and/or examples, and effects of each of the exemplary embodiments and/or examples can be achieved.

### INDUSTRIAL APPLICABILITY

According to the method for producing a semiconductor nanoparticle and the semiconductor nanoparticle according to the present invention, it is possible to provide a luminescence material having a narrow emission half width at half maximum, and the luminescence material can be used for bioimaging or bioassay at a high S/N. The semiconductor nanoparticle according to the present invention can also be applied to luminescence material applications of sensors and displays other than bio-applications.

### REFERENCE MARKS IN THE DRAWINGS

10A, 10B: semiconductor nanoparticle
11A, 11B: core part of semiconductor nanoparticle
12B: shell part of semiconductor nanoparticle
13: ligand
30: peak position of absorption spectrum
40: peak position of emission spectrum
41: emission half width at half maximum of emission spectrum

1. A method for producing a semiconductor nanoparticle, the method comprising:
mixing a Zn ion source solution and a Te ion source solution to prepare a precursor solution; and
putting the precursor solution in a closed container and heating the precursor solution,
wherein the preparing the precursor solution includes adjusting a pH of the precursor solution to 5 or more and 9 or less, and
the preparing the precursor solution and the heating the precursor solution include removing oxygen in the precursor solution to have an oxygen concentration of 2 mg/L or less in the precursor solution.

2. The method according to claim 1, wherein the preparing the precursor solution includes adding a ligand in the precursor solution.

3. The method according to claim 2, wherein the ligand is water-soluble and contains a mercapto group or a disulfide group.

4. The method according to claim 2, wherein
in the preparing the precursor solution, Zn ions in the Zn ion source solution, Te ions in the Te ion source solution, and the ligand have a molar ratio below:
Zn ions:Te ions:ligand=1:a:b,
where, a is 0.03 or more and 0.90 or less, and b is 1.0 or more and 9.0 or less.

5. The method according to claim 1, further comprising cooling the precursor solution putted in the closed container.

6. The method according to claim 1, wherein the heating the precursor solution includes heating the precursor solution at a temperature of 60° C. or more and 300° C. or less.

7. A semiconductor nanoparticle comprising:
a core part having a zinc blende structure of ZnTe; and
a ligand bonded to an atom on a surface of the core part.

8. The semiconductor nanoparticle according to claim 7, wherein the ligand is water-soluble and contains a mercapto group or a disulfide group.

9. The semiconductor nanoparticle according to claim 7, wherein
the ligand contains sulfur(S), and
the semiconductor nanoparticle has a composition that satisfies a condition below:
$$2.7 \times {d}^{\hat{}} ( - 1.2 ) > S / Te ,$$
where d is a particle size of the semiconductor nanoparticle.

10. The semiconductor nanoparticle according to claim 7, wherein the semiconductor nanoparticle has a particle size of 10 nm or less.

11. The semiconductor nanoparticle according to claim 7, wherein the semiconductor nanoparticle has an emission half width at half maximum of 50 nm or less.

12. The semiconductor nanoparticle according to claim 7, wherein a difference between a peak position in an absorption spectrum of the semiconductor nanoparticle and a peak position in an emission spectrum of the semiconductor nanoparticle is 60 nm or less.
